(19) United States
(12) Patent Application Publication
(10) Pub. No.: US 2006/0039429 A1
(43) Pub. Date: Feb. 23, 2006

(54) Device for bi-directional optical communication and method for fabricating the same

(75) Inventors: Chul Chae Choi, Bucheon-si (KR); Min Soo Noh, Yongin-si (KR)

Correspondence Address: BIRCH STEWART KOLASCH & BIRCH, PO BOX 747, FALLS CHURCH, VA, 22040-0747, US

(73) Assignee: LG Electronics Inc.

(21) Appl. No.: 11/205,186

(22) Filed: Aug. 17, 2005

(30) Foreign Application Priority Data
Aug. 18, 2004 (KR) 65192/2004

(51) Int. Cl. H01S 5/00; H01S 3/04

(52) U.S. Cl. 372/43.01

(57) ABSTRACT

A device for bi-directional optical communication and a method of fabricating the same, whereby a monolithic surface light emitting laser and an optical detector are integrally formed to make a fabricating process simple, and the optical detector is placed about the surface light emitting laser, enabling to carry out light emitting and light receiving functions with one device.

### BACKGROUND OF THE INVENTION

1. Field of the Invention

The present invention relates to a device for bi-directional optical communication and a method for fabricating the same, and more particularly to a device for bi-directional optical communication and a method of fabricating the same configured to integrally form a monolithic surface light emitting laser with an optical detector, which makes a fabricating process simple, and configured to place the optical detector about the surface light emitting laser, enabling to carry out light emitting and light receiving functions with one device.

2. Description of the Prior Art

Generally, it is essential to use an optical waveguide for embodying long distance or high speed communications. An optical communication is largely composed of a laser for generating a modulated light, an optical waveguide for transmitting the modulated light, and an optical detector for transforming the transmitted light to an electrical signal. Various methods have been used to embody a by-directional communication using one optical waveguide in a communication employing a light as a medium.

First of all, there is proposed a method for embodying a bi-directional communication using a complicated structure or a light having two different wavelengths but not-so-easy packaging process of parts in these methods and increased fabricating costs involved therein have resulted in a disadvantage of enlarging the package.

As another method of embodying a bi-directional communication, there is proposed a method in which a semiconductor laser is situated at and bonded to a central surface of an optical detector semiconductor but this method has also posed a problem in that bonding of two different kinds of optical semiconductors (semiconductor laser and photo diode) involved therein has brought about an inconvenient fabricating process.

Still another method has been proposed in which light detecting elements and light generating elements are stacked on an upper surface of a substrate, where light is detected from one side of the substrate, and light is emitted from the other side of the substrate. This structure however has also resulted in a considerable disadvantage in that an optical detector and a light source are fabricated in one continuous process to bring about an inconvenient bond with an optical waveguide, albeit easy in fabrication.

### SUMMARY OF THE INVENTION

The present invention is conceived to solve the afore-mentioned problems and it is an object of the present invention to provide a device for bi-directional optical communication and a method of fabricating the same configured to integrally form a monolithic surface light emitting laser with an optical detector to enable to simplify a fabricating process, and to place an optical detector about a surface light emitting laser to enable to carry out light emitting and light receiving functions with one element.

In accordance with a first aspect of the present invention, there is provided a device for bi-directional optical communication comprising: a semiconductor substrate; a first Distributed Bragg Reflector (DBR) layer formed on an upper surface of the semi-conductor substrate; an active layer formed on an upper surface of the first DBR layer; a second DBR layer formed on an upper surface of the active layer; a cap layer formed for ohmic contact with an electrode on the upper surface of the second DBR layer; an etch stop layer formed on an upper surface of the cap layer; a light absorbing layer formed on an upper surface of the etch stop layer; an upper electrode formed at the upper surface of the cap layer exposed to a vacancy formed by removing a central region of the light absorbing layer and the etch stop layer; a lower electrode formed at a lower surface of the first DBR layer; and a pair of metal patterns formed at the upper surface of the light absorbing layer, each spaced a predetermined distance apart.

In accordance with a second aspect of the present invention, there is provided a device for bi-directional optical communication comprising: a semiconductor substrate; a first DBR layer formed on an upper surface of the semiconductor substrate; an active layer formed on an upper surface of the first DBR layer; a second DBR layer formed on an upper surface of the active layer; a cap layer formed for ohmic contact with an electrode on the upper surface of the second DBR layer; an etch stop layer formed at an upper surface of the cap layer; a light absorbing layer formed on an upper surface of the etch stop layer; n-type and p-type regions each doped and distanced from an upper surface of the light absorbing layer to the lower surface thereof; an upper electrode formed at an upper surface of the cap layer exposed to a vacancy formed by removing a central region of the light absorbing layer and the etch stop layer; a lower electrode formed at a lower surface of the first DBR layer; and a pair of electrode pads respectively formed at upper surfaces of the n-type and p-type regions of the light absorbing layer, each spaced a predetermined distance apart.

In accordance with a third aspect of the present invention, there is provided a device for bi-directional optical communication comprising: a semiconductor substrate; a first DBR layer formed at an upper surface of the semiconductor substrate; an active layer formed on an upper surface of the first DBR layer; a second DBR layer formed on an upper surface of the active layer; a cap layer formed for ohmic contact with an electrode on an upper surface of the second DBR layer; an etch stop layer formed at an upper surface of the cap layer; a first polarity semiconductor layer formed on the upper surface of the etch stop layer; a light absorbing layer formed at an upper surface of the first polarity semiconductor layer; a second polarity semiconductor layer having a polarity opposite to that of the first polarity semiconductor and formed on an upper surface of the light absorbing layer; a first electrode formed at an upper surface of the first polarity semiconductor layer exposed by removing part of the second polarity semiconductor layer and the light absorbing layer; a second electrode formed at an upper surface of the second polarity semiconductor layer; an upper electrode formed at the upper surface of the cap layer exposed to a vacancy formed by removing a central region from the second polarity semiconductor layer to the etch stop layer; a lower electrode formed at a lower surface of the first DBR layer; and a pair of electrode pads respectively formed at upper surfaces of the n-type and p-type regions of the light absorbing layer, each spaced a predetermined distance apart.

In accordance with a fourth aspect of the present invention, there is provided a device for bi-directional optical communication comprising: a first structure including an active layer for emitting light by receiving an optical transmitting current; and a second structure formed at an upper surface of the first structure and for absorbing the incident light to generate an electric charge and for collecting the generated electric charge to transmit an electric signal.

In accordance with a fifth aspect of the present invention, there is provided a fabricating method of device for bi-directional optical communication, the method comprising the steps of: stacking a first DBR layer on an upper surface of a semiconductor substrate (first step); forming an active layer on the first DBR layer for generating a light (second step); forming a second DBR layer on an upper surface of the active layer (third step); forming a cap layer on an upper surface of the second DBR layer for ohmic contact (fourth step); forming an etch stop layer on the cap layer and then forming a light absorbing layer on the etch stop (fifth step); etching a central region of the light absorbing layer to the etch stop layer using an etching mask and then etching a region of the etch stop layer exposed by the light absorbing layer being etched to thereby expose the cap layer (sixth step); forming an upper electrode on an upper surface of the exposed cap layer to form a lower electrode at a lower surface of the semiconductor substrate (seventh step); and forming a pair of metal patterns respectively connected to a pair of electrode pads at an upper surface of the light absorbing layer, each spaced a predetermined distance apart (eighth step).

The above and other objects, features and advantages of the present invention will become apparent from the following description with reference to the accompanying drawings which illustrate examples of the present invention.

### BRIEF DESCRIPTION OF THE DRAWINGS

FIG. 1 is a schematic cross-sectional view of a device for bi-directional optical communication according to a first embodiment of the present invention.

FIGS. 2a to 2h are schematic cross-sectional views illustrating a fabricating process of a device for bi-directional optical communication according to the first embodiment of the present invention.

FIG. 3 is a schematic cross-sectional view illustrating a process of forming a current blocking layer between a second DBR layer and an active layer according to the first embodiment of the present invention.

FIGS. 4a and 4b are schematic upper surface view of a device for bi-directional optical communication according to the first embodiment of the present invention.

FIG. 5 is a schematic cross-sectional view of a device for bi-directional optical communication according to the first embodiment of the present invention.

FIG. 6 is a schematic cross-sectional view illustrating n-type and p-type regions formed on a light absorbing layer according to a second embodiment of the present invention.

FIG. 7 is a schematic cross-sectional view of a device for bi-directional optical communication according to a third embodiment of the present invention.

### DETAILED DESCRIPTION OF THE INVENTION

Now, preferred embodiments of the present invention will be described in detail with reference to the accompanying drawings.

The present invention is such that a surface light emitting laser device and an optical detector are integrally formed to enable to carry out a bi-directional communication with one device.

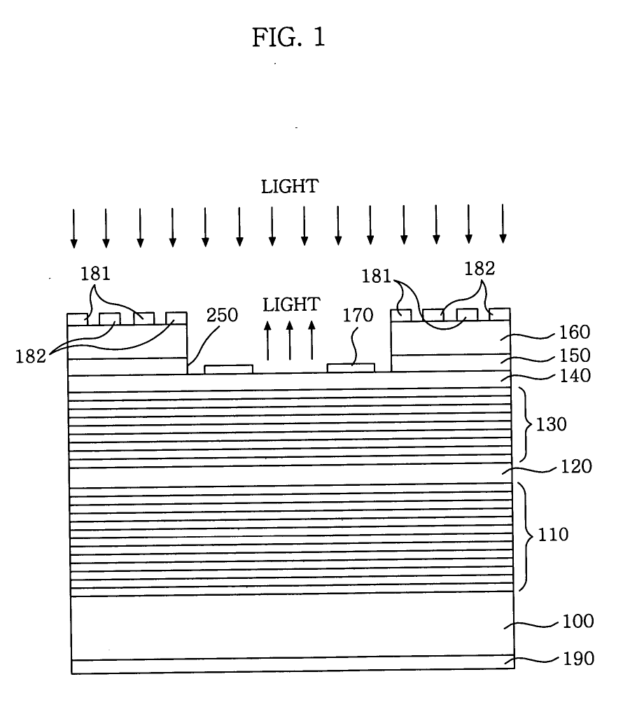

FIG. 1 is a schematic cross-sectional view of a device for bi-directional optical communication according to a first embodiment of the present invention. The device according to FIG. 1 comprises: a semiconductor substrate (100) a first Distributed Bragg Reflector (DBR) layer (110) formed on an upper surface of the semiconductor substrate (100); an active layer (120) formed on an upper surface of the first DBR layer 110); a second DBR layer (130) formed on an upper surface of the active layer (120); a cap layer (140) formed for ohmic contact with an electrode on the upper surface of the second DBR layer (130); an etching prevention layer (150) formed on an upper surface of the cap layer (140); a light absorbing layer (160) formed on an upper surface of the etching prevention layer (150); an upper electrode (170) formed at the upper surface of the cap layer (140) exposed to a vacancy (250) formed by removing a central region of the light absorbing layer (160) and the etching prevention layer (150); a lower electrode (190) formed at a lower surface of the first DBR layer (110); and a pair of metal patterns (181, 182) formed at the upper surface of the light absorbing layer (160), each spaced a predetermined distance apart.

The first embodiment of the present invention is such that a surface light emitting laser device and a Metal Semiconductor Metal (MSM) optical detector are integrally formed. When a modulated current is injected via the upper electrode (170) during an optical transmission being carried out using laser, the current is injected into the active layer (120) to generate a light, and a modulated laser light is emitted upwards reciprocating between the first and second DBR layers (110. 130).

Furthermore, a light incident from outside during light reception is received from an upper side of the device. At this time, the incident light is absorbed by the light absorbing layer (160), and electrons and holes are generated from the light absorbing layer (160). The metal patterns (181. 182) collect electric charges generated by the light absorbing layer (150) to transmit an electric signal to an external circuit.

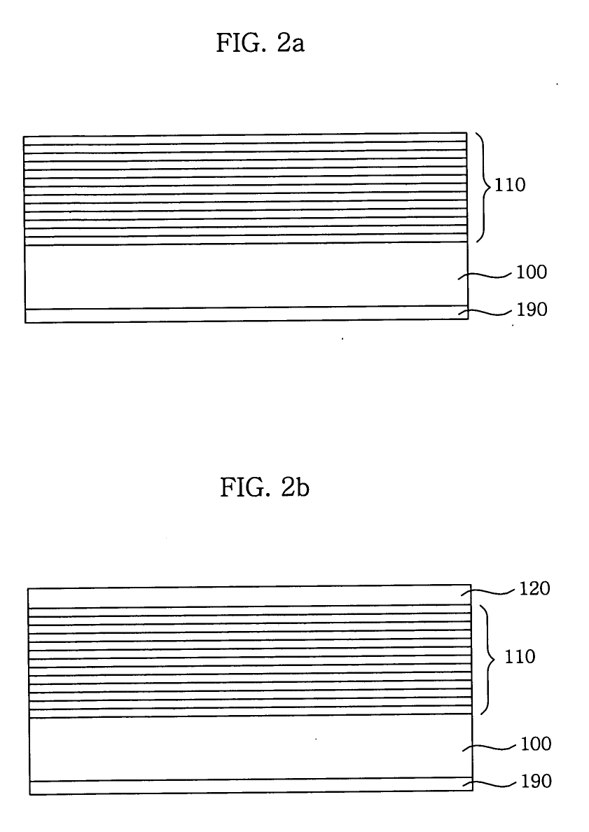

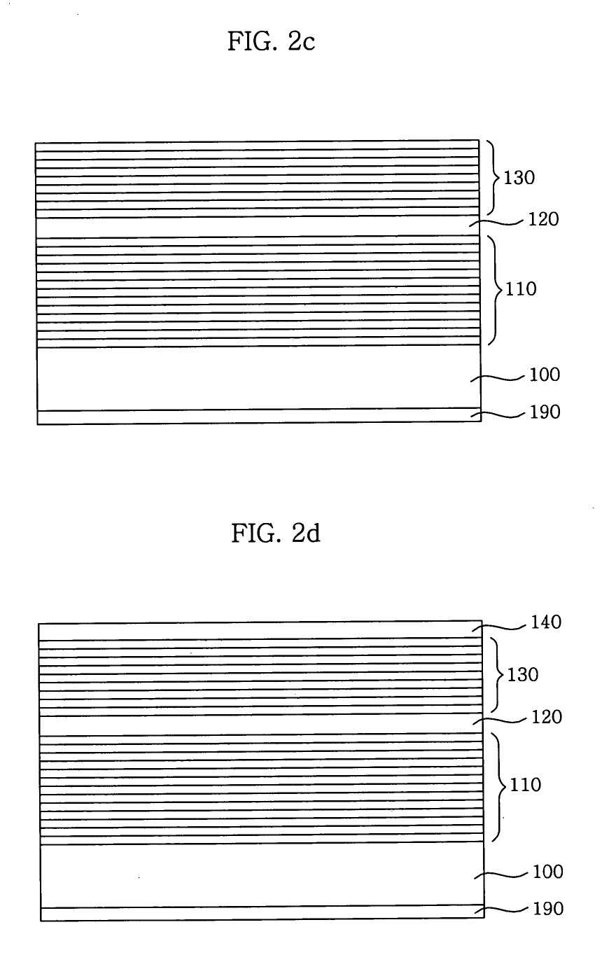

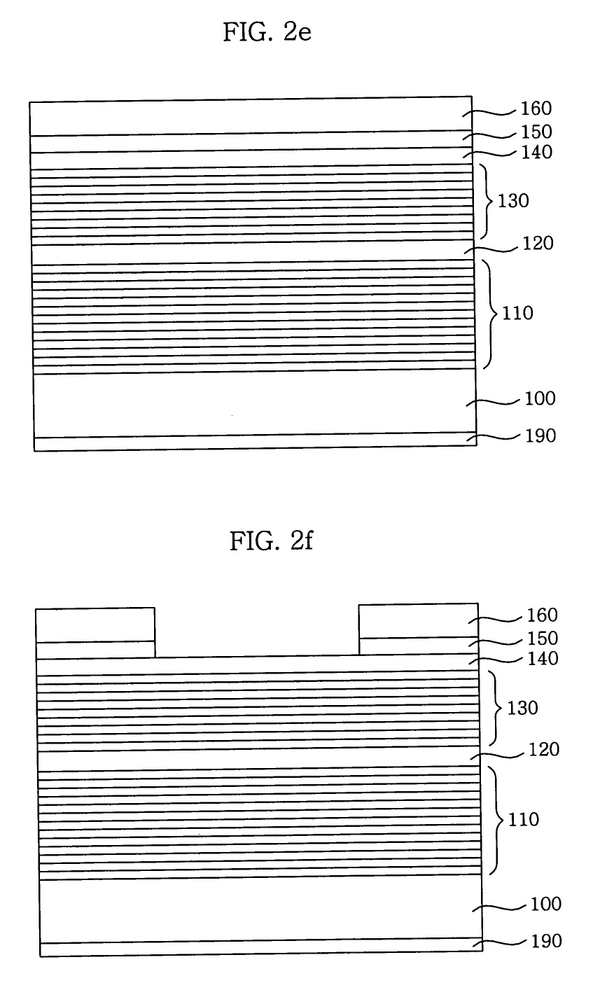

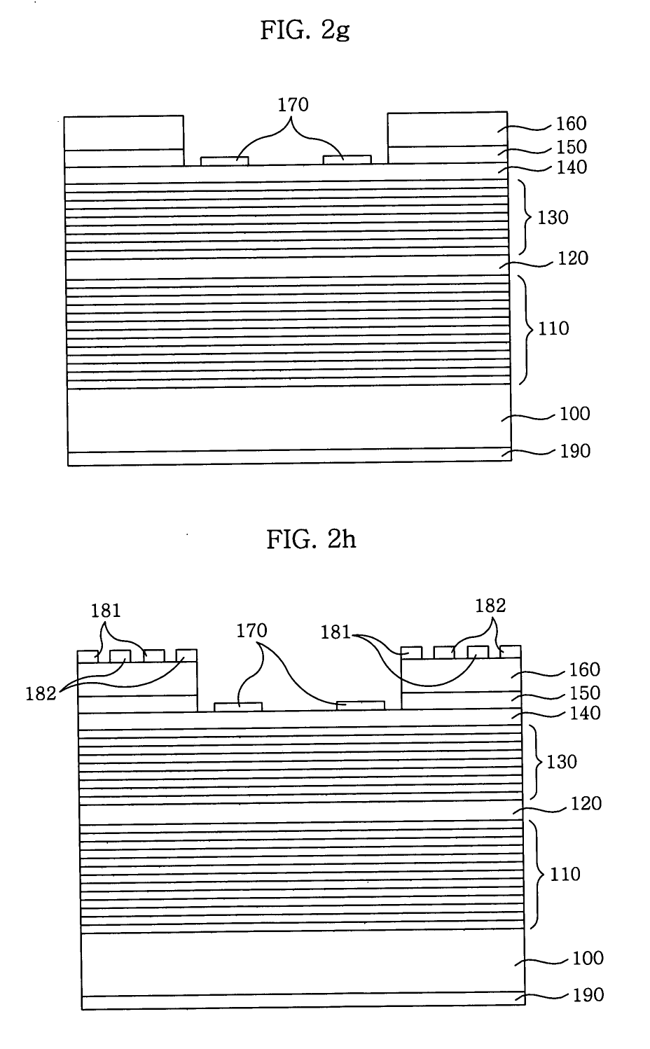

FIGS. 2a to 2h are schematic cross-sectional views illustrating a fabricating process of a device for bi-directional optical communication according to the first embodiment of the present invention.

First of all, the semiconductor substrate (100) is stacked thereon with the first DBR (Distributed Bragg Reflector) layer (110) using MBE (Molecular Beam Epitaxy) or MOCVD (Metal Organic Chemical Vapor Deposition) methods (see FIG. 2a). The first DBR layer (110) is alternatively stacked with high refractive index AlₓGa₁₋ₓAs layers and low refractive index AlₓGa₁₋ₓAs layers each having an optical thickness of (¼) λ.

In other words, the first DBR layer (110) is formed by stacking scores of layers of high refractive index AlₓGa₁₋ₓAs layers and low refractive index AlₓGa₁₋ₓAs layers.

Furthermore, the AlₓGa₁₋ₓAs layer can be changed of its refractive index by changing aluminum composition, where the changeable aluminum composition x is from 0 to 1.

The aluminum composition x of high refractive index AlₓGa₁₋ₓAs layer is 0.16 [symbol] , and aluminum composition x of low refractive index AlₓGa₁₋ₓAs layer is 0.92. Furthermore, the first DBR layer (110) is doped with p-type or n-type dopant to allow the current to flow.

Thereafter, the first DBR layer (110) is formed thereon with the active layer (120) for generating a light (see FIG. 2b). The active layer (110) is composed of several quantum wells wrapped by barrier layer. InGaP quantum well is used for the active layer (120) and AlGaInP is used for the barrier layer in order to embody the red surface light emitting laser.

Furthermore, in the case of near infrared laser, the active layer (120) is composed of GaAs quantum well and AlₓGa₁₋ₓAs barrier layer.

Thereafter, the active layer (120) is formed thereon with the second 2 DBR layer (130) (see FIG. 2c).

The second DBR layer (130) has a polarity opposite to that of the first DBR layer (110), and is doped with n-type dopant or p-type dopant. The second DBR layer (130) has a similar structure as that of the DBR layer (110), except that the albedo is designed to be lower than that of the first DBR layer (110).

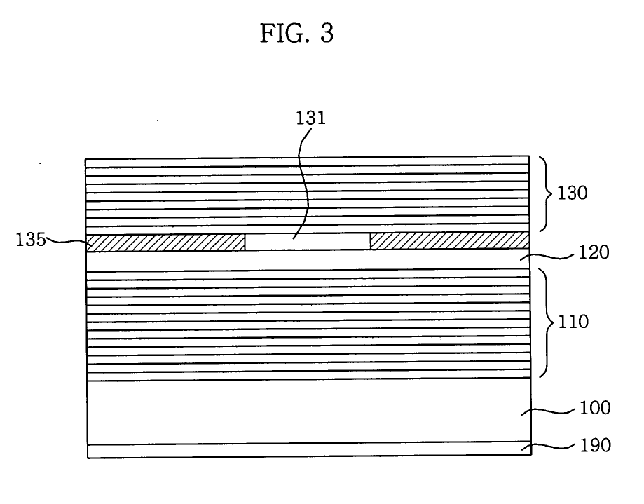

Meanwhile, as shown in FIG. 3, as an option, between the active layer (120) and the second DBR layer (130) there is formed an AlₓGa₁₋ₓAs layer (131) of high aluminum composition x of 0.9˜0.95, and when a lateral surface of the AlₓGa₁₋ₓAs layer (131) is selectively oxidized, the lateral surface is only oxidized but an inside thereof is not oxidized.

In other words, the lateral surface of the AlₓGa₁₋ₓAs layer (131) becomes an insulating membrane, and becomes a current blocking layer (135) for blocking the current flowing into the second DBR layer (130) after the device is fabricated.

Therefore, between the active layer (120) and the second DBR layer (130), there is laterally formed the current blocking layer (135), and a semiconductor layer made of the same material as that of the second DBR layer (130) is further disposed.

Successively, a thin cap layer (140) doped with a high density of approximate 1×10¹⁹ is formed on the second DBR layer (130) for ohmic contact (see FIG. 2d).

Preferably, the semiconductor substrate (100) and the cap layer (140) are formed with GaAs.

Successively, the cap layer (140) is formed thereon with the etch stop layer (150) of AlₓGa₁₋ₓAs composition, and the etch stop layer (150) is formed thereon with undoped light absorbing layer (160) of thickness of 0.5˜10 μm (see FIG. 2e). In other words, the light absorbing layer (160) is formed with intrinsic semiconductor.

Then, a central region of the light absorbing layer (160) is etched up to the etch stop layer (150) by etch to expose the cap layer (140) (see FIG. 2f). The etched and exposed cap layer (140) becomes a release surface of surface light emitting laser.

Successively, the exposed cap layer (140) is formed thereon with the upper electrode (170), and the GaAs substrate (100) is formed thereunder with the lower electrode (190) (see FIG. 2g). Then, as a process of forming an MSM optical detector, the light absorbing layer (150) is connected thereon by a pair of electrode pads to form a pair of metal patterns (181. 182), each spaced a predetermined distance apart (see FIG. 2h).

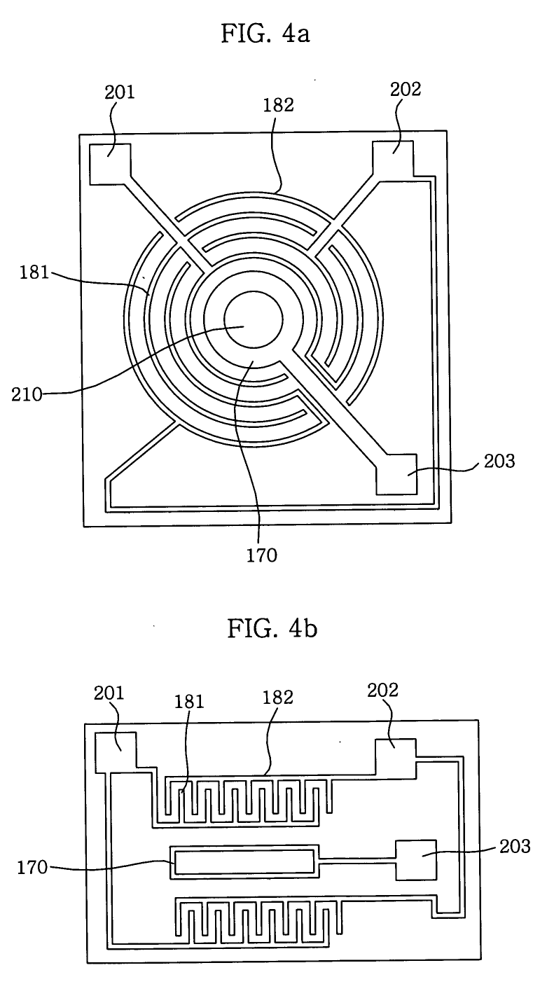

FIGS. 4a and 4b are schematic upper surface view of a device for bi-directional optical communication according to the first embodiment of the present invention, where the metal patterns of the MSM optical detector disposed at the device for bi-directional optical communication according to the present invention are concentrically formed about the upper electrode or formed each in an interdigital shape at both sides of the upper electrode.

Referring to FIG. 4a, a pair of metal patterns (181. 182) respectively connected to a pair of electrode pads (210. 202) formed at an upper surface of the light absorbing layer (150) are concentrically formed about the upper electrode (170).

The upper electrode (170), as mentioned earlier, is formed in ring shape at the upper surface of the cap layer (140) exposed in FIG. 2f, and the cap layer exposed inside the upper electrode (170) of ring shape becomes a light release outlet (210). Of course, the upper electrode (170) is connected to an electrode pad (203).

Now, referring to FIG. 4b, the pair of metal patterns (181. 182) respectively connected to the pair of electrode pads (210. 202) formed at the upper surface of the light absorbing layer (150) are each formed in an interdigital shape at both sides of the upper electrode (170). As shown in FIGS. 4a and 4b, the optical detector according to the present invention is concentrically arranged or at both sides about the surface light emitting laser.

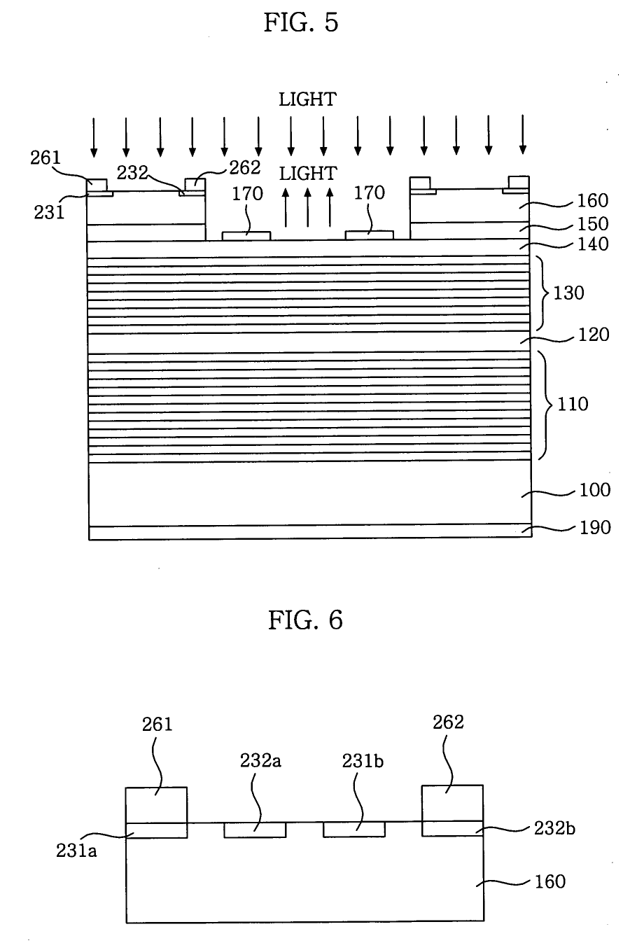

FIG. 5 is a schematic cross-sectional view of a device for bi-directional optical communication according to the first embodiment of the present invention. The device for bi-directional optical communication comprises: a semiconductor substrate (100); a first DBR layer (110) formed on an upper surface of the semiconductor substrate (100); an active layer (120) formed on an upper surface of the first DBR layer (110); a second DBR layer (130) formed on an upper surface of the active layer (120); a cap layer (140) formed for ohmic contact with an electrode on the upper surface of the second DBR layer (130); an etch stop layer (150) formed at an upper surface of the cap layer (140); a light absorbing layer (160) formed on an upper surface of the etch stop layer (150); n-type and p-type regions (231. 232) each doped and distanced from an upper surface of the light absorbing layer (160) to the lower surface thereof; an upper electrode (170) formed at an upper surface of the cap layer (140) exposed to a vacancy (250) formed by removing a central region of the light absorbing layer (160) and the etch stop layer (150); a lower electrode (190) formed at a lower surface of the first DBR layer (110); and a pair of electrode pads (261. 262) respectively formed at upper surfaces of the n-type and p-type regions (231. 232) of the light absorbing layer, each spaced a predetermined distance apart.

The second embodiment of the present invention formed with PIN type optical detector is more excellent in terms of light absorption efficiency because metal patterns do not block the light absorbing layer compared with the MSM optical detector of the first embodiment.

Furthermore, the n-type and p-type regions (231. 232) are thin such that most of the light is incident on the light absorbing layer (160) because there is very little absorption of light, and the electric charge generated by the light absorbing layer (160) is collected by the electrode pads (261. 262) and transmitted to outside equipment.

The n-type and p-type regions may be alternatively formed to distance the n-type region from the p-type region as in n-p-n-p. In other words, the n-type and p-type regions (231. 232) may be plurally formed, and as shown in FIG. 6, a first n-type region (231a), a light absorbing layer, a first p-type region (232a), a light absorbing layer, a second n-type region (231b), a light absorbing layer, and a second n-type (232b) are sequentially connected to form a structure of two PIN type optical detectors being connected.

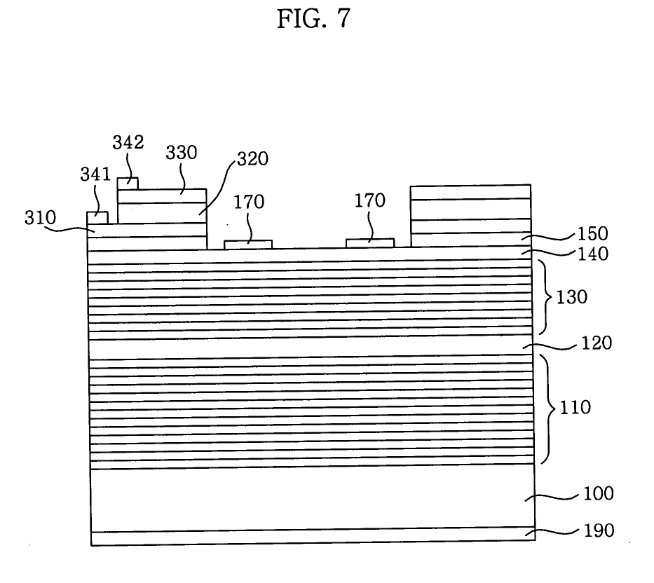

FIG. 7 is a schematic cross-sectional view of a device for bi-directional optical communication according to a third embodiment of the present invention. The device for bi-directional optical communication according to the third embodiment of the present invention comprises: a semiconductor substrate (100); a first DBR layer (110) formed at an upper surface of the semiconductor substrate (100); an active layer (120) formed on an upper surface of the first DBR layer (110); a second DBR layer (130) formed on an upper surface of the active layer (120); a cap layer (140) formed for ohmic contact with an electrode on an upper surface of the second DBR layer (130); an etch stop layer (150) formed at an upper surface of the cap layer (140); a first polarity semiconductor layer (310) formed on the upper surface of the etch stop layer (150); a light absorbing layer (320) formed at an upper surface of the first polarity semiconductor layer (310); a second polarity semiconductor layer (330) having a polarity opposite to that of the first polarity semiconductor (310) and formed on an upper surface of the light absorbing layer (320); a first electrode (341) formed at an upper surface of the first polarity semiconductor layer (310) exposed by removing part of the second polarity semiconductor layer (330) and the light absorbing layer (320); a second electrode (342) formed at an upper surface of the second polarity semiconductor layer (330); an upper electrode (170) formed at the upper surface of the cap layer (140) exposed to a vacancy (250) formed by removing a central region from the second polarity semiconductor layer (330) to the etch stop layer (150); and a lower electrode (190) formed at a lower surface of the first DBR layer (110).

If the first polarity semiconductor layer (310) is p-type semiconductor layer, the second polarity semiconductor layer (330) is n-type semiconductor layer.

The device for bi-directional optical communication according to the third embodiment of the present invention is formed with PIN type optical detector at an upper surface of the surface light emitting laser.

As mentioned earlier, the device for bi-directional optical communication can be defined by a first structure including an active layer for emitting light by receiving an optical transmitting current, and a second structure formed at an upper surface of the first structure and for absorbing the incident light to generate an electric charge and for collecting the generated electric charge to transmit an electric signal.

The first structure includes a stacked membrane in which a first DBR layer, an active layer and a second DBR layer are sequentially stacked. The second structure can be embodied by a light absorbing layer and a pair of metal patterns formed at an upper surface of the light absorbing layer, or can be embodied by a light absorbing layer, n-type and p-type regions respectively doped and distanced from a lower surface of the light absorbing layer, and a pair of electrode pads respectively formed at an upper surface of the n-type and p-type regions and respectively distanced therebetween.

The second structure can be also embodied by a stacked membrane in which a first polarity semiconductor layer, a light absorbing layer, a second polarity semiconductor layer are sequentially stacked.

Meanwhile, the metal patterns are concentrically or interdigitally formed.

As apparent from the foregoing, there is an advantage in the device for bi-directional optical communication thus described according to the present invention in that a monolithic surface light emitting laser and an optical detector are integrally formed to make a fabricating process simple, and the optical detector is placed about the surface light emitting laser, enabling to carry out light emitting and light receiving functions with one device. There is another advantage in that the surface light emitting laser centrally disposed at a single device can generate laser beams in response to the communication demand, where an optical detecting device can be used for laser monitoring. There is still another advantage in that the surface light emitting laser is under waiting mode, i.e., in the idle inoperative mode when light is incident on the device, and the incident light can be converted to an electric signal by the optical detecting device to be transmitted to the outside, such that the device according to the present invention can faithfully carry out optical transmission and reception.

Advantageous Effect

As mentioned in the foregoing, there is an effect in the present invention in that a monolithic surface light emitting laser and an optical detector are integrally formed to make a fabricating process simple, and the optical detector is placed about the surface light emitting laser, enabling to carry out light emitting and light receiving functions with one device.

While the invention has been described with reference to the several particular embodiments, it is to be understood that these embodiments are merely illustrative of the principles of the invention. Accordingly, the embodiments described in particular should be considered as exemplary, not limiting with respect to the following claims.

What is claimed is:

1. A device for bi-directional optical communication comprising: a semiconductor substrate; a first Distributed Bragg Reflector (DBR) layer formed on an upper surface of the semi-conductor substrate; an active layer formed on an upper surface of the first DBR layer; a second DBR layer formed on an upper surface of the active layer; a cap layer formed for ohmic contact with an electrode on the upper surface of the second DBR layer; an etch stop layer formed on an upper surface of the cap layer; a light absorbing layer formed on an upper surface of the etch stop layer; an upper electrode formed at the upper surface of the cap layer exposed to a vacancy formed by removing a central region of the light absorbing layer and the etch stop layer; a lower electrode formed at a lower surface of the first DBR layer; and a pair of metal patterns formed at the upper surface of the light absorbing layer, each spaced a predetermined distance apart.

2. A device for bi-directional optical communication comprising: a semiconductor substrate; a first DBR layer formed on an upper surface of the semiconductor substrate; an active layer formed on an upper surface of the first DBR layer; a second DBR layer formed on an upper surface of the active layer; a cap layer formed for ohmic contact with an electrode on the upper surface of the second DBR layer; an etch stop layer formed at an upper surface of the cap layer; a light absorbing layer formed on an upper surface of the etch stop layer; n-type and p-type regions each doped and distanced from an upper surface of the light absorbing layer to the lower surface thereof; an upper electrode formed at an upper surface of the cap layer exposed to a vacancy formed by removing a central region of the light absorbing layer and the etch stop layer; a lower electrode formed at a lower surface of the first DBR layer; and a pair of electrode pads respectively formed at upper surfaces of the n-type and p-type regions of the light absorbing layer, each spaced a predetermined distance apart.

3. A device for bi-directional optical communication comprising: a semiconductor substrate; a first DBR layer formed at an upper surface of the semiconductor substrate; an active layer formed on an upper surface of the first DBR layer; a second DBR layer formed on an upper surface of the active layer; a cap layer formed for ohmic contact with an electrode on an upper surface of the second DBR layer; an etch stop layer formed at an upper surface of the cap layer; a first polarity semiconductor layer formed on the upper surface of the etch stop layer; a light absorbing layer formed at an upper surface of the first polarity semiconductor layer; a second polarity semiconductor layer having a polarity opposite to that of the first polarity semiconductor and formed on an upper surface of the light absorbing layer; a first electrode formed at an upper surface of the first polarity semiconductor layer exposed by removing part of the second polarity semiconductor layer and the light absorbing layer; a second electrode formed at an upper surface of the second polarity semiconductor layer; an upper electrode formed at the upper surface of the cap layer exposed to a vacancy formed by removing a central region from the second polarity semiconductor layer to the etch stop layer; a lower electrode formed at a lower surface of the first DBR layer; and a pair of electrode pads respectively formed at upper surfaces of the n-type and p-type regions of the light absorbing layer, each spaced a predetermined distance apart.

4. The device as defined in claim 1, wherein the metal patterns are concentrically formed about the upper electrode, or interdigitally formed at both sides of the upper electrode.

5. The device as defined in claim 1, wherein a current blocking layer is laterally formed between the active layer and the second DBR layer.

6. The device as defined in claim 2, wherein a current blocking layer is laterally formed between the active layer and the second DBR layer, and a semiconductor layer having the same material as that of the second DBR layer is further disposed.

7. The device as defined in claim 3, wherein a current blocking layer is laterally formed between the active layer and the second DBR layer, and a semiconductor layer having the same material as that of the second DBR layer is further disposed.

8. The device as defined in claim 1, wherein the first and second DBR layers are AlₓGa₁₋ₓAs layers, and the first DBR layer is alternatively stacked with high refractive index AlₓGa₁₋ₓAs layers and low refractive index AlₓGa₁₋ₓAs layers each having an optical thickness of (¼) λ.

9. The device as defined in claim 2, wherein the first and second DBR layers are AlₓGa₁₋ₓAs layers, and the first DBR layer is alternatively stacked with high refractive index AlₓGa₁₋ₓAs layers and low refractive index AlₓGa₁₋ₓAs layers each having an optical thickness of (¼) λ.

10. The device as defined in claim 3, wherein the first and second DBR layers are AlₓGa₁₋ₓAs layers, and the first DBR layer is alternatively stacked with high refractive index AlₓGa₁₋ₓAs layers and low refractive index AlₓGa₁₋ₓAs layers each having an optical thickness of (¼) λ.

11. The device as defined in claim 1, wherein the first DBR layer is doped with dopant of different polarity than that of the second DBR layer.

12. The device as defined in claim 2, wherein the first DBR layer is doped with dopant of different polarity than that of the second DBR layer.

13. The device as defined in claim 3, wherein the first DBR layer is doped with dopant of different polarity than that of the second DBR layer.

14. A device for bi-directional optical communication comprising: a first structure including an active layer for emitting light by receiving an optical transmitting current; and a second structure formed at an upper surface of the first structure and for absorbing the incident light to generate an electric charge and for collecting the generated electric charge to transmit an electric signal.

15. The device as defined in claim 14, wherein the first structure comprises a stacked membrane in which a first DBR layer, an active layer and a second DBR layer are sequentially stacked.

16. The device as defined in claim 14, wherein the second structure comprises a light absorbing layer and a pair of metal patterns formed at an upper surface of the light absorbing layer.

17. The device as defined in claim 15, wherein the second structure comprises a light absorbing layer and a pair of metal patterns formed at an upper surface of the light absorbing layer.

18. The device as defined in claim 14, wherein the second structure comprises a light absorbing layer and n-type and p-type regions respectively doped and distanced from a lower surface of the light absorbing layer, and a pair of electrode pads respectively formed at an upper surface of the n-type and p-type regions and respectively distanced therebetween.

19. The device as defined in claim 15, wherein the second structure comprises a light absorbing layer and n-type and p-type regions respectively doped and distanced from a lower surface of the light absorbing layer, and a pair of electrode pads respectively formed at an upper surface of the n-type and p-type regions and respectively distanced therebetween.

20. The device as defined in claim 14, wherein the second structure comprises a stacked membrane in which a first polarity semiconductor layer, a light absorbing layer, a second polarity semiconductor layer are sequentially stacked.

21. The device as defined in claim 15, wherein the second structure comprises a stacked membrane in which a first polarity semiconductor layer, a light absorbing layer, a second polarity semiconductor layer are sequentially stacked.

22. The device as defined in claim 15, wherein the first DBR layer is doped with dopant of different polarity than that of the second DBR layer.

23. The device as defined in claim 16, wherein the metal patterns are concentrically or interdigitally formed.

24. A fabricating method of device for bi-directional optical communication, the method comprising the steps of: stacking a first DBR layer on an upper surface of a semiconductor substrate (first step); forming an active layer on the first DBR layer for generating a light (second step); forming a second DBR layer on an upper surface of the active layer (third step); forming a cap layer on an upper surface of the second DBR layer for ohmic contact (fourth step); forming an etch stop layer on the cap layer and then forming a light absorbing layer on the etch stop (fifth step); etching a central region of the light absorbing layer to the etch stop layer using an etching mask and then etching a region of the etch stop layer exposed by the light absorbing layer being etched to thereby expose the cap layer (sixth step); forming an upper electrode on an upper surface of the exposed cap layer to form a lower electrode at a lower surface of the semiconductor substrate (seventh step); and forming a pair of metal patterns respectively connected to a pair of electrode pads at an upper surface of the light absorbing layer, each spaced a predetermined distance apart (eighth step).

25. The method as defined in claim 24, wherein the semiconductor substrate and the cap layer are formed with GaAs, and the first and second DBR layers and the etch stop layer are formed with AlₓGa₁₋ₓAs.

26. The method as defined in claim 25, wherein, in the third step, an AlₓGa₁₋ₓAs layer of composition x of 0.9˜0.95 is formed between the active layer and the second DBR layer, and in the third and fourth steps, a step is further carried out for selectively oxidizing a lateral surface of the AlₓGa₁₋ₓAs layer.
